(19) United States
(12) Patent Application Publication
(10) Pub. No.: US 2016/0247945 A1
(43) Pub. Date: Aug. 25, 2016

(54) PHOTOVOLTAIC SOLAR CELL AND METHOD FOR PRODUCING A METALLIC CONTACT-CONNECTION OF A PHOTOVOLTAIC SOLAR CELL

(71) Applicant: FRAUNHOFER-GESELLSCHAFT ZUR FÖRDERUNG DER ANGEWANDTEN FORSCHUNG E.V., München (DE)

(72) Inventors: Julia Kumm, Freiburg (DE); Hassan Samadi, Erlangen (DE); Winfried Wolke, Freiburg (DE); Philip Hartmann, Freiburg (DE); Andreas Wolf, Freiburg (DE); Daniel Biro, Freiburg (DE)

(73) Assignee: Fraunhofer-Gesellschaft zur Forderung Der Angewand ten Forschung E.V., Munchen (DE)

(21) Appl. No.: 15/024,587

(22) PCT Filed: Sep. 23, 2014
(86) PCT No.: PCT/EP2014/070189

§ 371 Date: Mar. 24, 2016

(30) Foreign Application Priority Data
Sep. 27, 2013 (DE) 10 2013 219 560.5

(51) Int. Cl. H01L 31/02; H01L 31/18

(52) U.S. Cl. CPC H01L 31/02008; H01L 31/1868

(57) ABSTRACT

The invention relates to a method for producing a metallic contact-connection of a photovoltaic solar cell, including the following method steps: A providing a semiconductor substrate, and B applying an aluminum-containing contact-connection layer indirectly or directly to a side of the semiconductor substrate. The invention is characterized in that in a method step C, a diffusion barrier layer, which acts as a diffusion barrier at least with respect to aluminum, is applied indirectly or directly to the contact-connection layer, and in a method step D, a solderable layer comprised of a solderable material is applied indirectly or directly to the diffusion barrier layer, and in that the diffusion barrier layer and the contact-connection layer are applied by a PVD method.

### BACKGROUND

The invention relates to a photovoltaic solar cell and to a method for producing a metallic contact-connection of a photovoltaic solar cell.

Typical photovoltaic solar cells have metallization structures for the electrical contact-connection of the solar cell, for example for the electrical series connection of the solar cell to a neighboring solar cell by an electrically conductive cell connector in a solar cell module.

In the industrial production of photovoltaic solar cells, in particular of silicon solar cells, screen printing technology is typically used to form the abovementioned metallic contact structures. In this case, it is known to form metallic contact structures from a plurality of materials, in particular a plurality of metals, and to provide in particular a soldering pad embodied as a silver layer, which soldering pad can be electrically conductively connected to a cell connector by soldering methods known per se.

However, there are considerable opportunities to replace screen printing technology for producing metallic contact-connections in the industrial production of photovoltaic solar cells, in particular in order to enable higher efficiencies, to reduce the cell thickness and to save costs and contact material.

### SUMMARY

Therefore, the present invention is based on the object of providing a method for producing a metallic contact-connection of a photovoltaic solar cell and such a photovoltaic solar cell which enable production on an industrial scale and afford an alternative to screen printing technology mentioned above.

This object is achieved by a method for producing a metallic contact-connection of a photovoltaic solar cell with one or more features provided below. The wording of all the claims is hereby explicitly incorporated by reference in the description. The method according to the invention is preferably designed for forming a photovoltaic solar cell according to the invention, in particular an advantageous embodiment thereof. The photovoltaic solar cell according to the invention is preferably formed by the method according to the invention, in particular a preferred embodiment thereof.

The method according to the invention for producing a metallic contact-connection with a photovoltaic solar cell comprises the following method steps:

In a method step A, a semiconductor substrate is provided, and in a method step B, an aluminum-containing contact-connection layer is applied directly or preferably indirectly to a side of the semiconductor substrate. This contact-connection layer forms the electrically conductive connection to soldering points, to cell connectors or a busbar, for example. The contact layer therefore preferably has a sheet resistance of less than 50 mOhms, preferably less than 20 mOhms. Furthermore, the contact layer is advantageously embodied as a back-side mirror for reflecting the electromagnetic radiation not absorbed in the semiconductor substrate.

What is essential, then, is that in a method step C, a diffusion barrier layer, which acts as a diffusion barrier at least with respect to aluminum, is applied indirectly or preferably directly to the contact-connection layer. Furthermore, in a method step D, a solderable layer comprised of a solderable material is applied indirectly or preferably directly to the diffusion barrier layer.

The diffusion barrier layer and the contact-connection layer are applied in each case by a PVD method.

The present invention is based on the insight that the use of physical vapor deposition (PVD) for forming the contact-connection layer of a photovoltaic solar cell affords considerable advantages: PVD Al—in contrast to screen-printed Al—is able to contact not only p-doped but also moderately n-doped silicon with a low contact resistance, which makes it possible to implement novel cell concepts, for example with an n-doped base. Moreover, there is a cost advantage owing to saving of material: thinner wafers save semiconductor material costs and less contact material is required owing to the thinner application (for example 2 μm PVD Al instead of 20 μm SP Al). A major advantage is a lower material consumption of the solderable layer, for example of a silver layer, since only a very thin silver layer can be used over the whole area, instead of previously customary considerably thicker local silver pads, with the replacement thereof by NiV. The last advantage, in particular, is also based on the fact that the diffusion barrier can be produced by PVD very reliably in an impermeable manner and, therefore, the solderable layer is made so thin only in combination with the diffusion barrier applied by PVD.

In the industrial production of photovoltaic solar cells, however, hitherto use has substantially been made of the abovementioned screen printing technology for forming metallic contact-connection structures. PVD methods are not used particularly for forming an aluminum contact-connection layer. This is based on the fact, inter alia, that an aluminum-containing contact-connection layer applied by a PVD method cannot be electrically conductively connected, for example to a cell connector, by a customary soldering process.

The method according to the invention for the first time affords the possibility of nevertheless using, cost-effectively, an aluminum-containing contact-connection layer by PVD methods in the production of the metallic contact-connection structure of a photovoltaic solar cell.

For this purpose, as described above, in method step D a solderable layer is applied indirectly to the contact-connection layer, such that the solderable layer is electrically conductively connected to the contact-connection layer. The solderable layer can thus be electrically conductively connected to a cell connector by a soldering process by methods known per se and already tried and tested industrially.

What is crucial, however, is that an interdiffusion of aluminum from the contact-connection layer into the solderable layer must be avoided. This is because such an interdiffusion can lead to a formation of aluminum oxide at the outer surface of the solderable layer, with the result that the soldering process goes wrong.

For this reason, in the method according to the invention, in method step C, the diffusion barrier layer is arranged between contact-connection layer and solderable layer. The diffusion barrier layer is embodied in such a way that there is an electrically conductive connection between solderable layer and contact-connection layer, but on the other hand aluminum cannot diffuse through the diffusion barrier layer to the solderable layer.

This ensures, with little additional outlay, that no aluminum oxide forms at the outer surface of the solderable layer, such that by the method according to the invention for the first time on an industrial scale in the production of photovoltaic solar cells, or the interconnection thereof to form a solar cell module, a PVD method can be employed for forming the aluminum-based contact-connection layer.

Furthermore, both the contact-connection layer and the diffusion barrier layer are applied by a PVD method. This affords the advantage that both layers can be applied jointly without complexity in terms of apparatus.

A particularly simple and thus cost-effective method configuration arises in an advantageous embodiment in which the diffusion barrier layer is applied directly on the contact-connection layer. Alternatively or preferably additionally, an advantageous process simplification is achieved by virtue of the solderable layer being applied directly on the diffusion barrier layer.

In a further preferred embodiment, at least one, preferably exactly one, intermediate layer is applied between solderable layer and diffusion barrier layer. This intermediate layer affords the advantage that an increased adhesion between diffusion barrier layer and solderable layer can be obtained by the intermediate layer. Therefore, the intermediate layer is preferably embodied as a titanium intermediate layer, with further preference having a thickness in the range of 5 nm to 100 nm, with further preference 10 nm to 30 nm.

A further improvement in the method according to the invention and the solar cell according to the invention described below is achieved by virtue of oxygen being introduced into the diffusion barrier layer. Introducing oxygen into the diffusion barrier layer has the advantage that the barrier effect of the diffusion barrier layer is increased. This is the case particularly if the barrier layer has grain boundaries, since here oxygen also accumulates at least partly along the grain boundaries. If, in a subsequent method step, aluminum starts to diffuse into the grain boundaries, it impinges there on the oxygen, which typically forms an oxide with the aluminum. This aluminum oxide constitutes a particularly effective barrier to the diffusion of further aluminum and moreover blocks in particular the fast diffusion paths along the grain boundaries. A significantly greater thermal stability of the barrier layer against aluminum diffusion is achieved as a result.

Furthermore, the oxygen partly forms oxide compounds with the titanium intermediate layer, such that a compound or alloying of the titanium intermediate layer with the solderable material is reduced. The solderable material is thus contaminated to a lesser extent and, to ensure solderability, it suffices to apply thinner layers of the solderable material. A saving of material with regard to the cost-intensive solderable material is thus achieved.

If, as described above, an intermediate layer is arranged between solderable layer and diffusion barrier layer, in a further preferred embodiment oxygen is advantageously also introduced into the intermediate layer. This further increases the barrier effect with respect to the solderable material.

In particular, an increase in the barrier effect is achieved by virtue of the fact that, firstly, after applying the diffusion barrier layer and before applying the intermediate layer, oxygen is introduced into the diffusion barrier layer and, subsequently, after applying the intermediate layer, oxygen is introduced into the intermediate layer in a further, separate method step.

Oxygen is introduced into the diffusion barrier layer preferably from the gas phase. In particular, oxygen may already be introduced into the diffusion barrier layer and/or intermediate layer by the oxygen from the ambient atmosphere. Consequently, by discharging the semiconductor substrate from possible process chambers and bringing it into contact with ambient air at room temperature, preferably for a period in the range of 1 min to 24 h, introduction of oxygen can be achieved.

In one advantageous embodiment, oxygen is introduced in situ in a process chamber by virtue of the fact that after depositing the diffusion barrier layer and/or after depositing the intermediate layer, oxygen or an oxygen-containing gas mixture is guided into the process chamber.

The object mentioned above is furthermore achieved by a photovoltaic solar cell according to the invention. The photovoltaic solar cell according to the invention comprises a semiconductor substrate and an aluminum-containing contact-connection layer arranged indirectly or directly at a side of the semiconductor substrate, said aluminum-containing contact-connection layer, as contact-connection layer, being electrically conductively connected to the semiconductor substrate. What is essential is that a diffusion barrier layer, which acts as a diffusion barrier at least with respect to aluminum, is arranged indirectly or directly on the contact-connection layer, and that a solderable layer comprised of a solderable material is arranged indirectly or directly on the contact-connection layer. The contact-connection layer is electrically conductively connected to the solderable layer.

This affords the advantages mentioned in the case of the method according to the invention, in particular that the aluminum-containing contact-connection layer can be deposited by a PVD method.

In one advantageous embodiment, a particularly simple and cost-effective configuration results from the fact that the diffusion barrier layer is applied directly on the contact-connection layer, and the solderable layer is applied directly on the diffusion barrier layer.

Preferably, the diffusion barrier layer is embodied in a manner comprising one or a plurality of substances from the group Ti, N, W, O. In particular, the diffusion barrier layer is preferably embodied as a TiN layer, as a TiW layer, or as a TiWN layer. This affords the advantage that Ti and also W and N₂ are comparatively readily available and thus expedient (in contrast to Ta, for example). Nevertheless, TiN and TiW:N are very effective diffusion barriers against Al even during a thermal step.

In a further preferred embodiment of the method according to the invention at least the diffusion barrier layer and the solderable layer are applied in situ. The two aforementioned layers are thus applied in a PVD installation, without the semiconductor substrate being discharged between application of the two layers. As a result, the process time and also the process costs are reduced, since the process atmosphere for both layers need only be produced once and introducing and discharging processes are furthermore obviated.

In a further preferred embodiment, the contact-connection layer is also applied by a PVD method. In particular, it is advantageous that at least contact-connection layer, diffusion barrier layer and solderable layer are applied in situ. As a result, process time is furthermore saved and process costs are likewise saved.

In a further preferred embodiment of the method according to the invention, a heat treatment step is carried out between method step B and method step C. A heat treatment step is known per se and in the present case is preferably performed with temperatures in the range of 300° C. to 450° C. for a time duration in the range of 2 min to 30 min. This affords the advantage that without a heat treatment step the solar cell would have a poorer efficiency, since both passivation quality and electrical contact are usually improved by a thermal step. Moreover, damage possibly introduced, e.g. as a result of a sputtering or laser process, can be completely or partly repaired again during a heat treatment step. The heat treatment step thus constitutes an important boundary condition. Overall preferably only one heat treatment step is carried out, but it will preferably take place after Al metallization and, if appropriate, after contact formation by LFC.

In a further preferred embodiment, a heat treatment step is carried out after method step D. This affords the advantage that contact-connection layer, diffusion barrier layer and solderable layer are treated in a common heat treatment step and the coatings can be carried out jointly, such that a high vacuum for coating purposes has to be implemented only once.

In a further preferred embodiment of the method according to the invention, between method steps A and B, in a method step Al, a passivation layer is applied to the semiconductor substrate. Furthermore, in method step B the contact-connection layer is applied indirectly or preferably directly to the passivation layer and, after method step B, preferably after method step D, an electrically conductive connection between contact-connection layer and semiconductor substrate is produced at a plurality of local regions. As a result, an electrically conductive connection between contact-connection layer and semiconductor substrate is in each case produced at a multiplicity of point-like contact-connection locations, such that a surface passivation of the semiconductor substrate is possible by the passivation layer and a sufficient electrical conductivity is nevertheless provided due to the multiplicity of so-called point contacts. In particular, it is advantageous to produce the point contacts by the LFC method known per se, as described in DE 10046170 A1, for example.

It thus lies within the scope of the invention, for the purpose of forming the electrically conductive connections in one method step, both for the passivation layer to be opened locally at a plurality of positions and for the electrically conductive connection to be produced. It likewise lies within the scope of the invention firstly to open the passivation layer locally at a plurality of positions and to produce the electrically conductive connection in a separate, subsequent method step. In particular, an outcome here that advantageously provides economy in the method and is thus cost-effective involves firstly forming the passivation layer with a plurality of local openings and then applying the contact-connection layer indirectly or preferably directly, such that when the contact-connection layer is applied, it penetrates through the passivation layer at the local openings and an electrically conductive connection to the semiconductor substrate arises in each case.

In order to ensure a stable implementability of the LFC method, the contact-connection layer or the entire stack of contact-connection layer, diffusion barrier and solderable layer advantageously has a layer thickness that is as thin as possible and, in particular, as homogeneous as possible.

The proposed layer stack is preferably formed with a total layer thickness of a few μm, preferably less than 5 μm, in particular less than 3 μm, in order to ensure fault-free production by the LFC method.

Deposition by PVD (in contrast to screen printing) and the small total thickness ensure high homogeneity (or a small absolute layer thickness fluctuation of max. 1 μm, more likely less) of the layer, such that the laser parameters can be set with low total power and very precisely. Damage to the semiconductor material can thus be minimized.

The laser parameters and/or the material parameters of the chosen layers when carrying out the LFC method are advantageously chosen in such a way that contact-connection layer and semiconductor substrate are locally melted, but the diffusion barrier layer is melted only slightly, and is preferably not melted. As a result, the local introduction of the material of the contact-connection layer into the semiconductor substrate is intensified and introduction of the material of the diffusion barrier layer and of the solderable layer into the semiconductor substrate is reduced, preferably avoided. Therefore, the use of a diffusion barrier layer having a higher melting point than the melting point of the contact-connection layer and the melting point of the semiconductor substrate is particularly advantageous; with preference there is a temperature difference between the melting points of at least 500° C., preferably at least 1000° C.

The use of titanium nitride as diffusion barrier layer is particularly advantageous, therefore, since this has a comparatively high melting point of approximately 2950° C., compared with a melting point for example of aluminum as contact-connection layer of 660° C.

In the above-described embodiment with use of the LFC method for forming the point contacts, it lies within the scope of the invention to carry out the formation of the LFC point contacts and a heat treatment step as described above before carrying out method steps C and D. This affords the advantage that the heat treatment step is already carried out before the solderable layer is applied, and the requirements made of the impenetrability of the diffusion barrier are thus less stringent.

In this case, it is particularly advantageous to clean, in particular to level, the contact-connection layer after carrying out the LFC method and before method step C in a method step C1. This improves the layer adhesion. In particular, it is advantageous to carry out the cleaning/leveling by isopropanol. It likewise lies within the scope of the invention, in addition to or instead of the cleaning, to apply a further layer, preferably a further aluminum layer, after carrying out the LFC method and before method step C, such that the diffusion barrier is applied to the further layer, in particular to an aluminum layer, in method step C.

The photovoltaic solar cell whose metallic contact-connection structure is formed by the method according to the invention, and/or the photovoltaic solar cell according to the invention is preferably embodied as a silicon solar cell known per se. In this case, it lies within the scope of the invention to form typical solar cell structures, with the difference that according to the invention for the purpose of forming at least one metallic contact-connection of the photovoltaic solar cell, as described above, an aluminum-containing contact-connection layer, a diffusion barrier layer and a solderable layer are applied, wherein at least diffusion barrier layer and contact-connection layer are applied by a PVD method.

In particular, it is advantageous for the solar cell according to the invention to be embodied as a PERC solar cell known per se, as described in Blakers et al., Applied Physics Letters, vol. 55 (1989) pp. 1363-5 or S. Mack et al., 35^{th} IEEE Photovoltaic Specialists Conference, 2010.

Preferably, the metallic contact-connection facing away from the incident radiation when the solar cell is used is formed by the method according to the invention. Such a contact-connection is typically referred to as back contact-connection.

As already explained above, the solar cell according to the invention is preferably embodied as a photovoltaic silicon solar cell. In particular, the semiconductor substrate is preferably embodied as a silicon wafer.

Method steps B and C are preferably carried out by PVD, in particular preferably in a common process, with further preference in situ. With further preference, method step D is also carried out by PVD, in particular in situ with method steps B and C.

### BRIEF DESCRIPTION OF THE DRAWINGS

Further preferred features and embodiments are described below with reference to the figures and exemplary embodiments. In the figures:

FIGS. 1 to 5 show an exemplary embodiment of a method according to the invention for producing a metallic contact-connection of a photovoltaic solar cell, and

FIGS. 6 to 8 show an exemplary embodiment of a method according to the invention for producing a metallic contact-connection of a back-contactable photovoltaic solar cell.

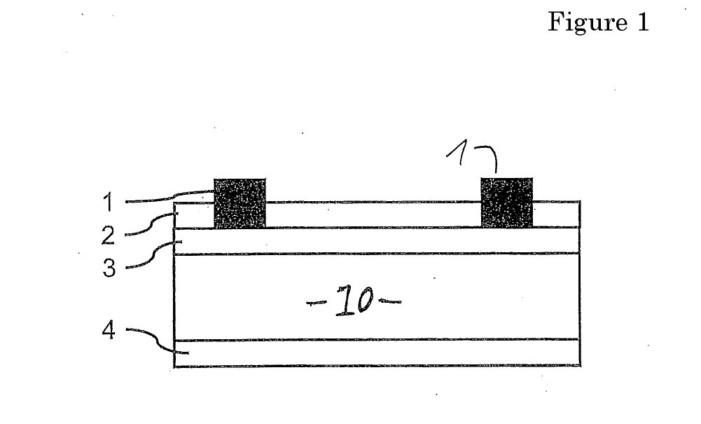

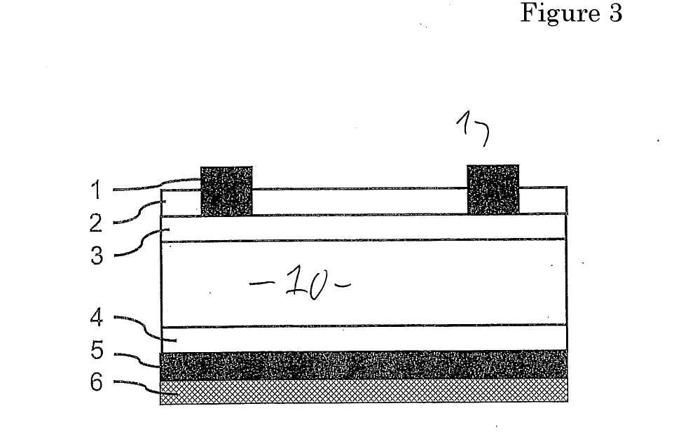

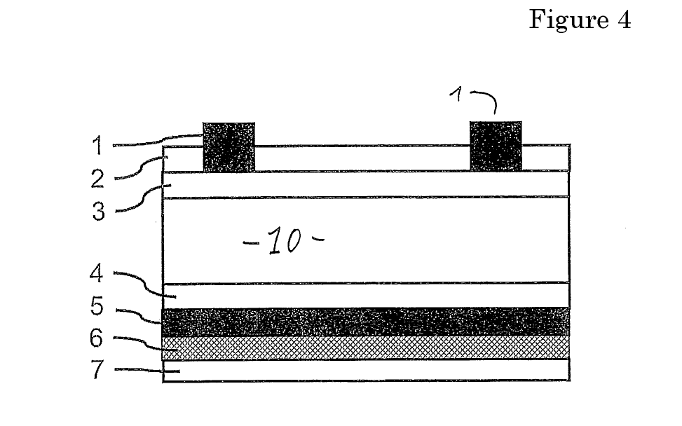

FIGS. 1 to 8 show schematic partial sections, not true to scale, of a solar cell in the respective method stage. In this case, the solar cell continues approximately mirror-symmetrically toward the right and left.

In FIGS. 1 to 8, identical reference signs designate identical or identically acting elements.

### DETAILED DESCRIPTION OF THE PREFERRED EMBODIMENTS

FIG. 1 shows the exemplary embodiment of the method according to the invention after a method step A, in which a semiconductor substrate 10 embodied as a silicon wafer is provided.

In FIGS. 1 to 5, the front side of the solar cell, which faces the light incidence during use, is illustrated at the top in each case. The semiconductor substrate 10 has an emitter 3 at the front side. This emitter can be formed by diffusion in the semiconductor substrate 10. It is likewise possible to fit the emitter 3 as a dedicated layer on the semiconductor substrate 10.

In the exemplary embodiment illustrated, the semiconductor substrate 10 as base is p-doped and the emitter is n-doped. A reversal of the doping types likewise lies within the scope of the invention.

A passivating optical antireflection layer 2, which can be embodied as a silicon nitride layer in a manner known per se, is arranged on the emitter 3.

Furthermore, a metallic front contact-connection, which can be embodied in a manner known per se as a comb-like or double-comb-like contact-connection structure known per se, is arranged at the front side. By way of example, two metallic fingers 1 of the front contact-connection, which run perpendicularly to the plane of the drawing, are illustrated in the partial sectional illustration in FIGS. 1 to 5. The fingers 1 penetrate through the antireflection layer 2 and are electrically conductively connected to the emitter 3.

At the back side, i.e. at the side of the semiconductor substrate 10 which faces away from the incident radiation during use, in a method step Al a passivation layer 4 is applied to the semiconductor substrate 10 over the whole area.

The passivation layer is formed as an Al₂O₃ layer by PECVD and has a thickness in the range of 20 nm to 200 nm, in the present case of approximately 100 nm. Likewise, the passivation layer can consist wholly or partly of thermally produced SiO₂ and can be applied as an SiNₓ layer or SiOₓ layer wholly or partly by PECVD.

In a method step B, a contact-connection layer 5 embodied as an aluminum layer is then applied to the passivation layer 4 at the back side in a manner covering said passivation layer over the whole area. The contact-connection layer 5 is produced in a PVD method.

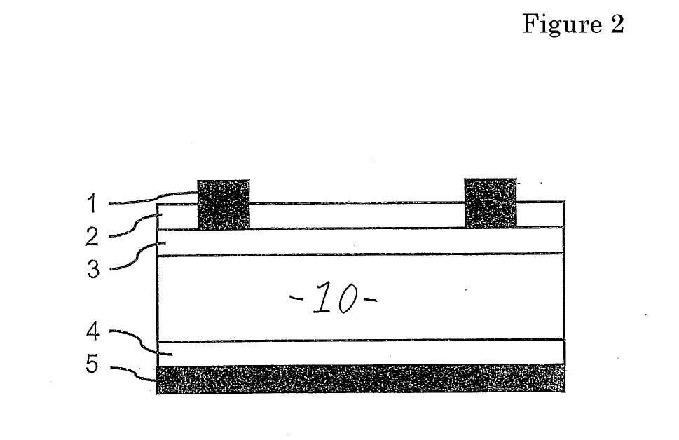

The result is illustrated in FIG. 2.

Afterward, in a method step C a diffusion barrier layer 6 embodied as a TiN layer is applied, likewise by a PVD method. The diffusion barrier layer has a thickness in the range of 20 nm to 300 nm, in the present case of approximately 100 nm.

Afterward, a thin Ti layer having a thickness in the range of 1 nm to 50 nm, in the present case approximately 25 nm, is inserted, which serves as an adhesion promoter between Ag and TiN.

In a subsequent method step D, a solderable layer 7 embodied as a silver layer is applied as a cover layer in a manner covering the diffusion barrier layer 6 over the whole area, likewise by a PVD method.

In this case, contact-connection layer 5, diffusion barrier layer 6 and solderable layer 7 are applied in situ, such that particularly process-economic and thus cost-saving production is effected.

Alternatively, the solderable layer 7 is formed of NiV or NiCr, which is protected against oxidation by a thin Ag layer, if appropriate. A Ti adhesion promoter layer can be dispensed with in this embodiment.

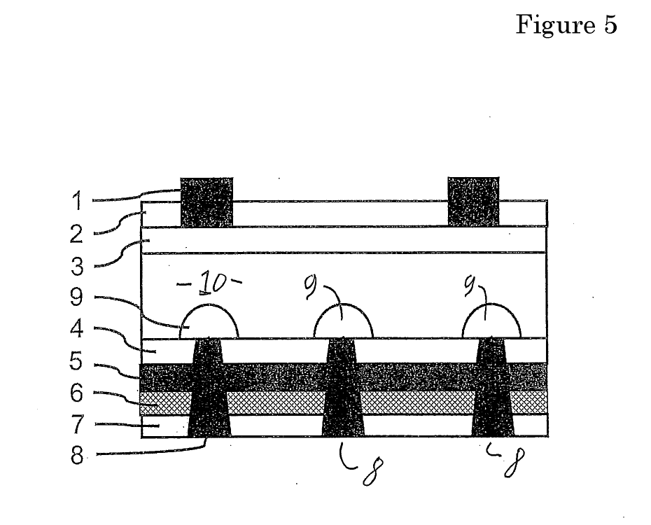

In a subsequent method step, in a manner known per se by locally melting a multiplicity of point-like regions by an LFC method, a multiplicity of electrical point contacts 8 are produced, the result is illustrated in FIG. 5:

The local melting gives rise to a point-like electrical contact-connection which penetrates through the passivation layer 4, in particular. Furthermore, in the solidification process, an aluminum-doped high doping region 9 is in each case produced locally at the contact-connection points and decreases the contact resistance and the surface recombination at the contacts and thus further increases the efficiency of the solar cell. The local melting is carried out in such a way that a temperature above the melting points of contact-connection layer 5 and semiconductor substrate 10, but below the melting point of the diffusion barrier layer 6, is present. The diffusion barrier layer is thus not melted or is melted only slightly. As a result, the local introduction of the material of the contact-connection layer into the semiconductor substrate is intensified and penetration of the material of the diffusion barrier layer and of the solderable layer into the semiconductor substrate is avoided or at least reduced.

FIG. 5 thus likewise illustrates an exemplary embodiment of a photovoltaic solar cell according to the invention, comprising the semiconductor substrate 10, with the contact-connection layer 5 embodied as an aluminum layer and arranged directly at the back side, said contact-connection layer being electrically conductively connected to the semiconductor substrate 10 in a manner penetrating through the passivation layer 4 in a point-like fashion. The diffusion barrier layer 6, which acts as a diffusion barrier at least with respect to the aluminum, is arranged directly on the contact-connection layer. The solderable layer 7 embodied as a silver layer is arranged on the diffusion barrier layer 6 (with an interposed adhesion promoter layer comprising titanium). As described above, the contact-connection layer 5 is electrically conductively connected firstly to the semiconductor substrate 10 and secondly to the solderable layer 7.

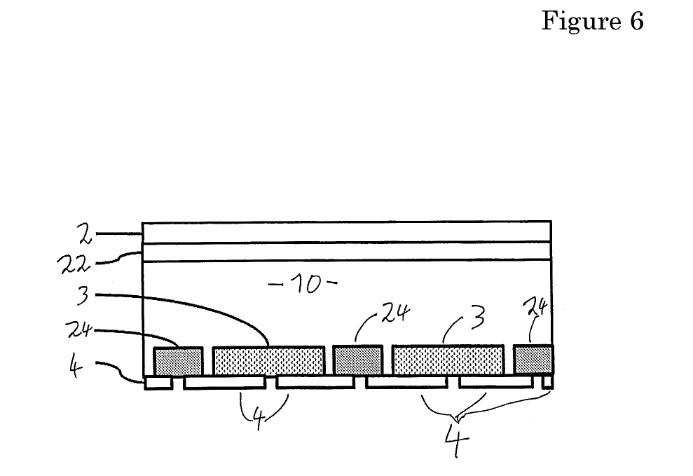

FIGS. 6 to 8 show a second exemplary embodiment of a method according to the invention. Therefore, in order to avoid repetition, in particular the differences with respect to the first exemplary embodiment in accordance with FIGS. 1 to 5 are discussed below:

As already mentioned, the method according to the invention can be employed particularly advantageously for back-contacted solar cells. In the case of back-contacted photovoltaic solar cells, one or a plurality of metallic contact-connection structures for contacting one or a plurality of emitter regions and also one or a plurality of metallic contact-connection structures for contacting one or a plurality of base regions of the solar cell are arranged on the side facing away from the incident radiation. Back-contacted solar cells have the advantage that shading of the front side by metallic contact structures does not occur and, furthermore, simpler series interconnection in a solar cell module is possible.

In FIGS. 6 to 8 as well, the front side of the solar cell, which faces the light incidence during use, is illustrated at the top in each case. FIG. 6 shows the second exemplary embodiment of the method according to the invention after a method step A, in which a semiconductor substrate 10 embodied as a silicon wafer is provided. In the present case, the semiconductor substrate is n-doped and has a highly n-doped region at the front side, the so-called front surface field (FSF) 22. The front side of the photovoltaic solar cell is covered by an antireflection layer 2. At the back side of the semiconductor substrate 10, emitter regions 3 (p-doped) and a plurality of n-doped high doping regions, so-called back surface field (BSF) 24, are formed by diffusion of corresponding dopants.

A passivation layer 4 is applied on the back side of the semiconductor substrate 10 in a method step A1. The passivation layer 4 was applied over the whole area and opened locally at each emitter region 3 and at each BSF region 24.

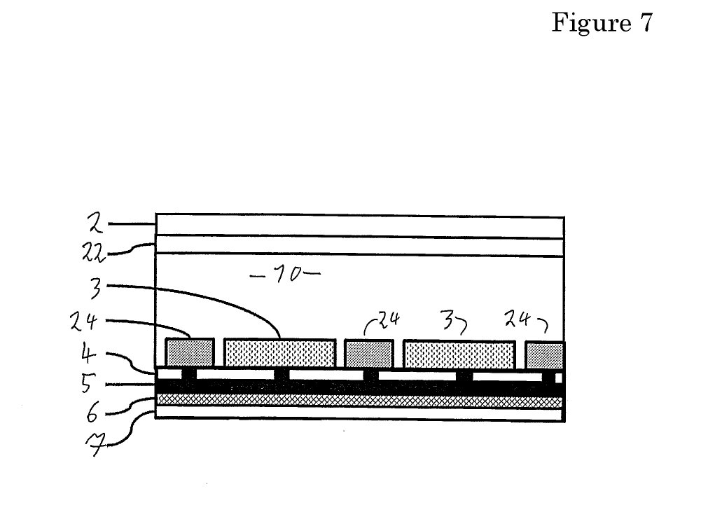

FIG. 7 shows the state after a method step B, in which a contact-connection layer 5 embodied as an aluminum layer was applied to the back side over the whole area. At the above-described cutouts of the passivation layer 4, the aluminum layer penetrates through the passivation layer, such that an electrical contact-connection both of the emitter regions 3 and of the BSF regions 24 is present in this method state.

A diffusion barrier layer 6 embodied as a TiN layer is applied to the contact-connection layer 5. The diffusion barrier layer 6 is in turn covered over the whole area by a solderable layer 7, formed from silver in the present case.

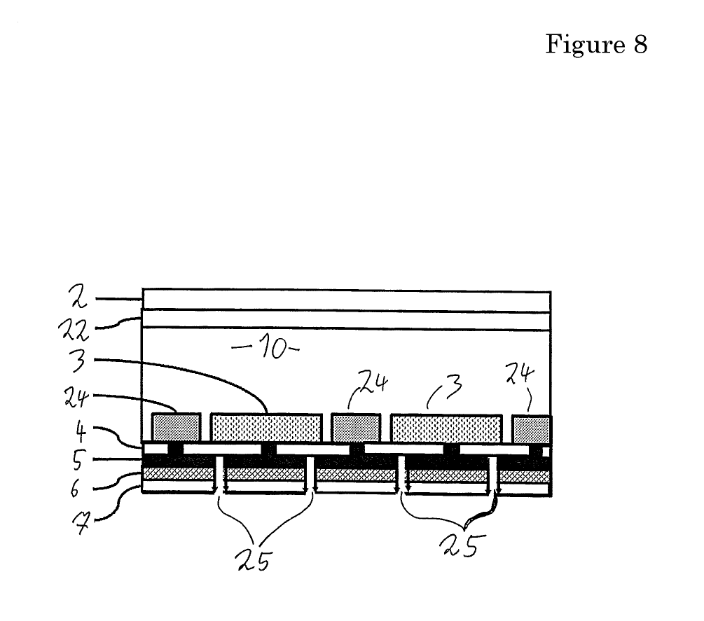

Finally, FIG. 8 shows a method state in which an electrical separation of the metallic contact-connection for the emitter regions 3, on the one hand, and the BSF regions 24, on the other hand, was effected by virtue of the fact that solderable layer 7, diffusion barrier layer 6 and contact-connection layer 5 were severed, resulting in the formation of trenches 25 between the opposite polarization types for the purpose of electrical insulation.

In this case, the metallic contact-connection structures can be embodied as comb-like or double-comb-like structures in a manner known per se. In particular, the embodiment as intermeshing comb-like structures, so-called “interdigitated contacts”, which is known in the case of back contact cells, is advantageous.

1. A method for producing a metallic contact-connection of a photovoltaic solar cell, comprising the following method steps:
A providing a semiconductor substrate;
B applying an aluminum-containing contact-connection layer (5) indirectly or directly to a side of the semiconductor substrate;
C applying a diffusion barrier layer, which acts as a diffusion barrier at least with respect to aluminum, indirectly or directly to the contact-connection layer (5); and D applying a solderable layer (7) comprised of a solderable material directly or indirectly to the diffusion barrier layer (6);
wherein the diffusion barrier layer (6) and the contact-connection layer (5) are applied by a PVD method.

2. The method as claimed in claim 1, wherein the diffusion barrier layer (6) is embodied in a manner comprising one or a plurality of substances of the group Ti, N, W, or O.

3. The method as claimed in claim 1, wherein at least the diffusion barrier layer (6) and the solderable layer (7) are applied in situ.

4. The method as claimed in claim 1, wherein the solderable layer (7) is applied by a PVD method.

5. The method as claimed in claim 1, wherein the diffusion barrier layer (6) is applied directly on the contact-connection layer (5).

6. The method as claimed in claim 1, further comprising applying the contact-connection layer (5) to the semiconductor substrate indirectly with interposition of at least one electrically insulating intermediate layer, producing an electrically conductive connection between contact-connection layer (5) and semiconductor substrate by an LFC method, after carrying out the LFC method subsequently the method steps C and D are carried out, and between carrying out the LFC method and the method step C, at least one of cleaning or leveling the contact-connection layer (5) by isopropanol or by applying a further layer.

7. The method as claimed in claim 1, further comprising carrying out a heat treatment step between method steps B and C, or carrying out a heat treatment step after method step D, or both.

8. The method as claimed in claim 1, further comprising between method steps A and B, in a method step A1, applying a passivation layer (4) to the semiconductor substrate (10), in method step B, applying the contact-connection layer (5) indirectly or directly to the passivation layer (4), and after method step B, at a plurality of local regions, producing an electrically conductive connection between contact-connection layer (5) and semiconductor substrate (10), and carrying out a heat treatment step after producing the electrically conductive connection between contact-connection layer and semiconductor substrate.

9. The method as claimed in claim 1, further comprising introducing oxygen into the diffusion barrier layer.

10. The method as claimed in claim 19, further comprising after applying the diffusion barrier layer and before applying a further layer, introducing oxygen into the diffusion barrier layer and, after applying the intermediate layer and before applying a further layer, introducing oxygen into the intermediate layer.

11. The method as claimed in claim 10, wherein the oxygen is introduced in situ in a processing chamber, by oxygen or an oxygen-containing gas mixture being guided into the processing chamber, after the deposition of the diffusion barrier layer or of the intermediate layer, or each of the diffusion barrier layer and the intermediate layer.

12. A photovoltaic solar cell, comprising a semiconductor substrate (10) and an aluminum-containing contact-connection layer arranged indirectly or directly at a side of the semiconductor substrate, said contact-connection layer (5) being electrically conductively connected to the semiconductor substrate (10), a diffusion barrier layer (6), which acts as a diffusion barrier at least with respect to aluminum, applied on the contact-connection layer (5), and a solderable layer (7) comprised of a solderable material arranged on the diffusion barrier layer (6), and the contact-connection layer (5) is electrically conductively connected to the solderable layer.

13. The solar cell as claimed in claim 12, wherein the diffusion barrier layer (6) is applied directly on the contact-connection layer (5) and the solderable layer (7) is applied directly on the diffusion barrier layer (6).

14. The solar cell as claimed in claim 12, wherein the diffusion barrier layer (6) is embodied in a manner comprising one or a plurality of substances of the group Ti, N, W, or O.

15. The solar cell as claimed in claim 12, wherein the solar cell is embodied as a back-contactable solar cell having at least one n-doped region and at least one p-doped region at a back side thereof.

16. The method as claimed in claim 1, wherein the diffusion barrier layer is embodied as a TiN layer, as a TiW layer or as a TiWN layer.

17. The method as claimed in claim 1, wherein at least the contact-connection layer, the diffusion barrier layer (6) and the solderable layer (7) are applied in situ.

18. The method as claimed in claim 1, wherein the diffusion barrier layer (6) is applied directly on the contact-connection layer (5) and the solderable layer (7) is applied directly on the diffusion barrier layer (6).

19. The method as claimed in claim 1, wherein at least one intermediate layer is applied between solderable layer (7) and diffusion barrier layer (6).

20. The solar cell as claimed in claim 12, wherein the diffusion barrier layer is embodied as a TiN layer, as a TiW layer or as a TiWN layer.
